(19) United States
(12) Patent Application Publication
(10) Pub. No.: US 2014/0070883 A1
(43) Pub. Date: Mar. 13, 2014

(54) High Efficiency Amplifier

(71) Applicants: Mark Gurvich, Costa Mesa, CA (US); JianQing He, Cypress, CA (US)

(72) Inventors: Mark Gurvich, Costa Mesa, CA (US); JianQing He, Cypress, CA (US)

(21) Appl. No.: 13/690,778

(22) Filed: Nov. 30, 2012

Related U.S. Application Data
(60) Provisional application No. 61/699,590, filed on Sep. 11, 2012.

(51) Int. Cl. H03F 3/60

(52) U.S. Cl. CPC H03F 3/60
USPC 330/124 R

(57) ABSTRACT

High efficiency Doherty amplifiers are described. Contemplated Doherty amplifiers can include an input hybrid coupler having first and second inputs, and first and second drivers that individually drive respective first and second inputs. In this manner, the driver output power to the main and auxiliary amplifiers can be dynamically controlled as a function of an input signal's envelope. This advantageously allows for a substantial decrease in the amount of power wasted by the driver, especially when used with digitally modulated signals.

This application claims the benefit of priority to U.S. provisional application having Ser. No. 61/699,590 filed on Sep. 11, 2012. This and all other extrinsic materials discussed herein are incorporated by reference in their entirety. Where a definition or use of a term in an incorporated reference is inconsistent or contrary to the definition of that term provided herein, the definition of that term provided herein applies and the definition of that term in the reference does not apply.

### FIELD OF THE INVENTION

The field of the invention is amplifiers.

### BACKGROUND

The following background discussion includes information that may be useful in understanding the present invention. It is not an admission that any of the information provided herein is prior art or relevant to the presently claimed invention, or that any publication specifically or implicitly referenced is prior art.

Among other uses, Doherty amplifiers are widely used in wireless communications to amplify digitally modulated signals having non-constant envelopes. Under these signals, traditional Doherty amplifiers waste driver power at lower envelope power levels by generally splitting the driver output power between main and auxiliary amplifiers even when the auxiliary amplifier is not enabled. Unfortunately, this generally results in degradation of the Doherty amplifier's efficiency.

U.S. pat. publ. no. 2012/0025915 to Ui and U.S. Pat. No. 8,115,546 to Hong, et al. discuss various configurations of Doherty amplifiers are known in the art that have improved efficiencies over traditional Doherty amplifiers. In addition, EPO patent appl. no. 2372905 to Alcatel Lucent and U.S. Pat. No. 7,893,770 to Yamauchi et al. discuss various devices and arrangements that vary the voltage to main and auxiliary amplifiers to increase the Doherty amplifier's efficiency. Finally, the article “A High-Efficiency 100-W GaN Three-Way Doherty Amplifier for Base-Station Applications” discusses using GaN technology for 3-way Doherty amplifiers to increase efficiency.

However, in all of the references, a proportion of the driver's power directed between the main and auxiliary amplifiers remains constant, and does not depend on the input signal's envelope magnitude. In addition, none of the references known to Applicant contemplate individually driving first and second inputs of a hybrid coupler using first and second drivers to dynamically distribute driver output power between main and auxiliary amplifiers as a function of an input signal's envelope.

Thus, there is still a need for high efficiency Doherty amplifiers configured to dynamically distribute driver output power between main and auxiliary amplifiers.

### SUMMARY OF THE INVENTION

The inventive subject matter provides apparatus, systems and methods for increasing the efficiency of symmetrical or asymmetrical Doherty amplifiers. In especially preferred embodiments, the Doherty amplifiers operate under digitally-modulated signals with non-constant envelopes, such as those used by various wireless communication standards (e.g., CDMA, LTE, WiMAX, etc.). Preferred Doherty amplifiers include an input hybrid coupler having first and second inputs, and first and second drivers that individually drive the first and the second inputs of the hybrid coupler, respectively.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWING

FIG. 1 is a block diagram of a typical Doherty amplifier.

FIG. 2 is a block diagram of an embodiment of a high-efficiency Doherty amplifier.

FIG. 3 is a chart of the relative power going into Main and Auxiliary amplifiers of a Doherty amplifier.

FIG. 4 is a block diagram of another embodiment of a high-efficiency Doherty amplifier.

FIG. 5 is a chart showing auxiliary amplifier input phase at different coupling values.

FIGS. 6-8 are block diagrams of additional embodiments of high-efficiency Doherty amplifiers.

### DETAILED DESCRIPTION

One should appreciate that the disclosed techniques provide many advantageous technical effects including increasing the efficiency of Doherty amplifiers, especially when used with digitally modulated signals having non-constant envelopes.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

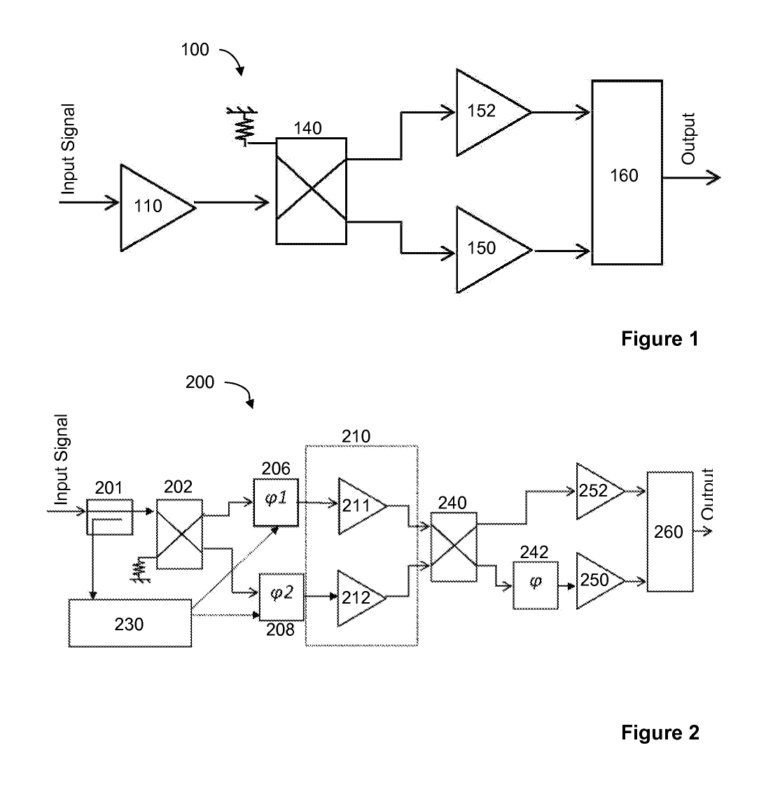

In FIG. 1, a block diagram illustrates a traditional Doherty amplifier 100. The Doherty amplifier 100 includes a main amplifier 150 and an auxiliary amplifier 152. The input signal is sent to driver 110, and the driver output is fed to a hybrid coupler 140. The hybrid coupler 140 statically splits the driver output between main and auxiliary amplifiers 150 and 152 at a constant ratio, often 1:1. The outputs of the main and auxiliary amplifiers 150 and 152 are combined in a Doherty combiner 160 and outputted as an amplified signal.

In a traditional Doherty amplifier, the proportion of driver output power directed between the main and auxiliary amplifiers 150 and 152 is constant regardless of the input signal's envelope magnitude. This static distribution of power wastes the driver's output power directed to the auxiliary amplifier 152 when the input power level is below a predetermined threshold because the auxiliary amplifier 152 of the Doherty amplifier 100 remains closed. This is especially problematic when the Doherty amplifier 100 is used with digitally modulated signals having high peak-to-average ratios because a substantial amount of the output power of the driver 110 (typically about 40-60%) is fed into the auxiliary amplifier 152 that is often closed. The wasted power results in a degradation of the amplifier's efficiency.

FIG. 2 illustrates a block diagram of one embodiment of an improved Doherty amplifier 200 having an efficiency that is greater than that of traditional Doherty amplifiers, especially when used in conjunction with digitally modulated signals. It is contemplated that the inventive subject matter discussed herein can increase the driver efficiency of the Doherty amplifier by a factor of about 1.7-2.0, or greater. This is turn can result in an increase in the overall amplifier's efficiency including the Doherty output stage and the driver by 3.0%-8.0%, or greater, depending on the configuration and RF signal modulation.

Doherty amplifier 200 includes an input power divider, which is preferably a hybrid coupler 202 although a directional coupler or a splitter could alternatively be used. The hybrid coupler 202 receives an input signal from directional coupler 201 and produces first and second inputs, which can be fed to first and second signal modulators 206 and 208. The first and second signal modulators 206 and 208 can be configured to adjust a phase of one or both of the first and second inputs, as needed. The first and second inputs can then be individually fed to first and second drivers 211 and 212, respectively (collectively driver 210).

In such embodiments, the first driver 211 can be configured to receive the first input signal that has a first input phase and a first input amplitude, and the second driver 212 can be configured to receive a second input signal that has a second input phase and a second input amplitude. Advantageously, the first and second drivers 210 and 211 can be configured and disposed within the Doherty amplifier 200, such that the drivers 210 and 211 can individually drive the first and second inputs of hybrid coupler 202. Because multiple signal modulators 206 and 208 are utilized in the Doherty amplifier 200, it is contemplated that the first and second input signals can have different input phases and/or amplitudes from one another.

A phase shifter controller 230 can be functionally coupled to the directional coupler 201 and the first and second signal modulators 206 and 208. The phase shift controller 230 preferably is configured to allow for dynamic adjustment of the phases of each of the first and second input signals using the first and second signal modulators 206 and 208. Preferred signal modulators include phase shifters, although vector modulators or any other commercially suitable signal modulator could be used. The phases of the first and second input signals can be adjusted across a dynamic range as a function of the input signal envelope power. In some contemplated embodiments, the dynamic range can be between about 5 dB to 15 dB, and more preferably between about 10 dB to 15 dB. However, the specific phases of the first and second input signals will likely depend on the parameters of the received input signal.

It is especially preferred that the adjustment to the first and second input phases across the dynamic range occurs such that a constant output signal phase is maintained across the dynamic range. An example of this is described below in reference to FIG. 5. The adjustments in phase are governed by the following relationships:

φ₁=φ₀−f(Pinp); and

φ₂=−φ₁.

where φ₀ is the initial phase value and f(Pinp) is the linear or non-linear function of the input power. Under these conditions:

P_{inpMain}=Pᵢₙₚ*Gd*Sin²(φ₁);

P_{inpAux}=Pᵢₙₚ*Gd*Sin²(φ₁);

φinpMain=φᵢₙₚ+φ₀; and

φ_{inpAux}=φᵢₙₚ+φ₀.

where Pᵢₙₚ is the amplifier input power, G_{d} is the Driver gain, P_{inpMain} is the input power of the main amplifier, P_{inpAux} is the input power of the main amplifier, φ_{inpMain} is the main amplifier input signal phase, φ_{inpAux} is the auxiliary amplifier input signal phase, φᵢₙₚ is the amplifier input signal phase, and φ₀ is a constant value.

It is further contemplated that one or both of the first and second input amplitudes can also be dynamically adjusted.

The outputs of the first and second drivers 211 and 212 can be fed to a hybrid coupler 240 or other power divider, which thereby directs the driver outputs to a main amplifier 250 and an auxiliary amplifier 252. The driver output to the main amplifier 250 is first fed to a fixed phase shifter 242 that shifts the phase of the output signal by a predetermined amount. The output of the main amplifier 250 can then be summed with the output of the auxiliary amplifier 252 in a Doherty combiner 260 and outputted as an amplified signal.

Thus, using the above described Doherty amplifier 200, the proportion of the driver's power directed to the auxiliary amplifier 252 relative to the main amplifier 250 can be controlled as a function of the input signal's envelope. For example, at the back-off where the input signal's envelope voltage is low, a majority of the power of the driver 210, and preferably, all of the power of the driver 210, goes to the main amplifier 250. At full power where the input signal's envelope reaches its maximum value, the output power of the driver 210 is distributed between the main and auxiliary amplifiers 250 and 252. In such embodiments, the proportion of the power distribution between the main and auxiliary amplifiers 250 and 252 may be 1:1, 1:2, 1:3, or any other commercially suitable proportion, depending on the specific application. Such proportion can be determined by one of ordinary skill in the art taking into account the above relationships.

Dynamic redistribution of driver output power between main and auxiliary amplifiers 250 and 252 advantageously allows for a substantial decrease of the power wasted by the driver 210. Such reduction in waste is critical in many applications including, for example, cellular communications, as it can substantially increase the battery life of cellular phones, for example.

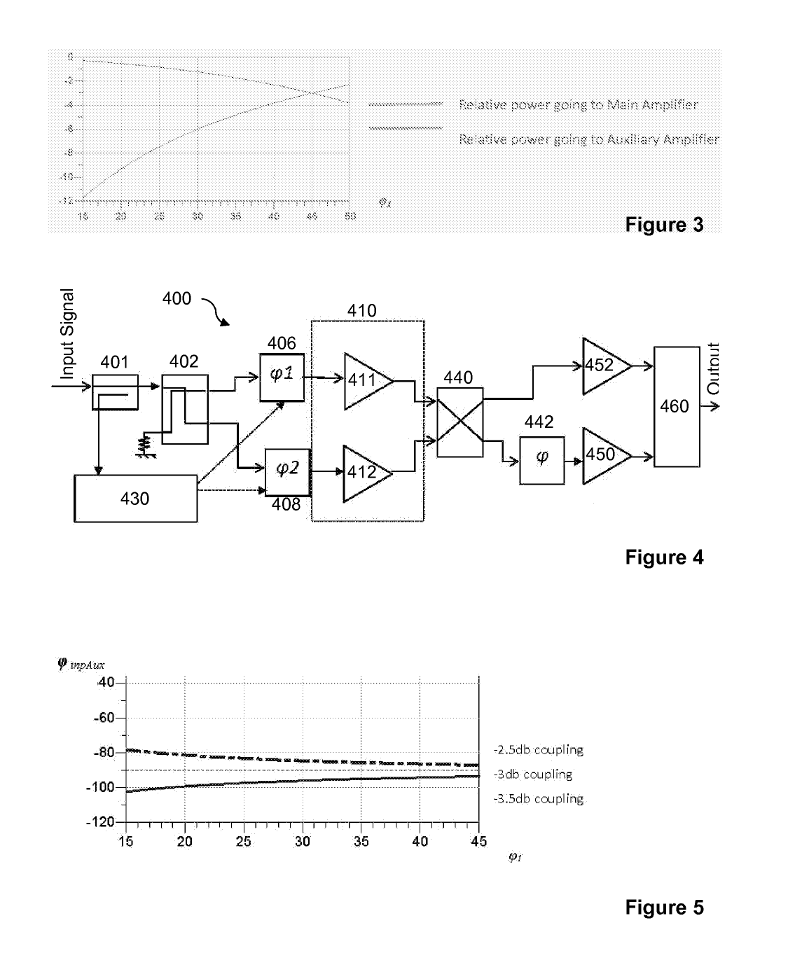

FIG. 3 illustrates one possible distribution of the relative power of the driver between main and auxiliary amplifiers as a function of the phase. In the graph shown in FIG. 3, φₒ=15 degrees and linear function φ=f(Pinp), i.e. φ=k*f(Pinp), where k is a coefficient.

Another embodiment of an improved Doherty amplifier 400 is shown in FIG. 4. The Doherty amplifier 400 includes a directional coupler 402 in place of the hybrid coupler of FIG. 2. The use of the directional coupler provides for uneven signal splitting, which results in unequal signal amplitudes of the first and second inputs to the first and second drivers 411 and 412.

In some contemplated embodiments, the directional coupler value could fall within a range of between about −1 db to about −10 db range. The choice of the coupling value provides auxiliary amplifier phase correction across the dynamic range of the input signal, and could contribute to amplifier linearization. With respect to the remaining numerals in FIG. 4, the same considerations for like components with like numerals of FIG. 2 apply.

FIG. 5 depicts exemplary input phases of the auxiliary amplifier at different coupling values. For example, at a 3 db coupling value, the embodiment shown in FIG. 5 becomes equivalent to the embodiment shown in FIG. 2, having a constant auxiliary amplifier phase across a range of input signals.

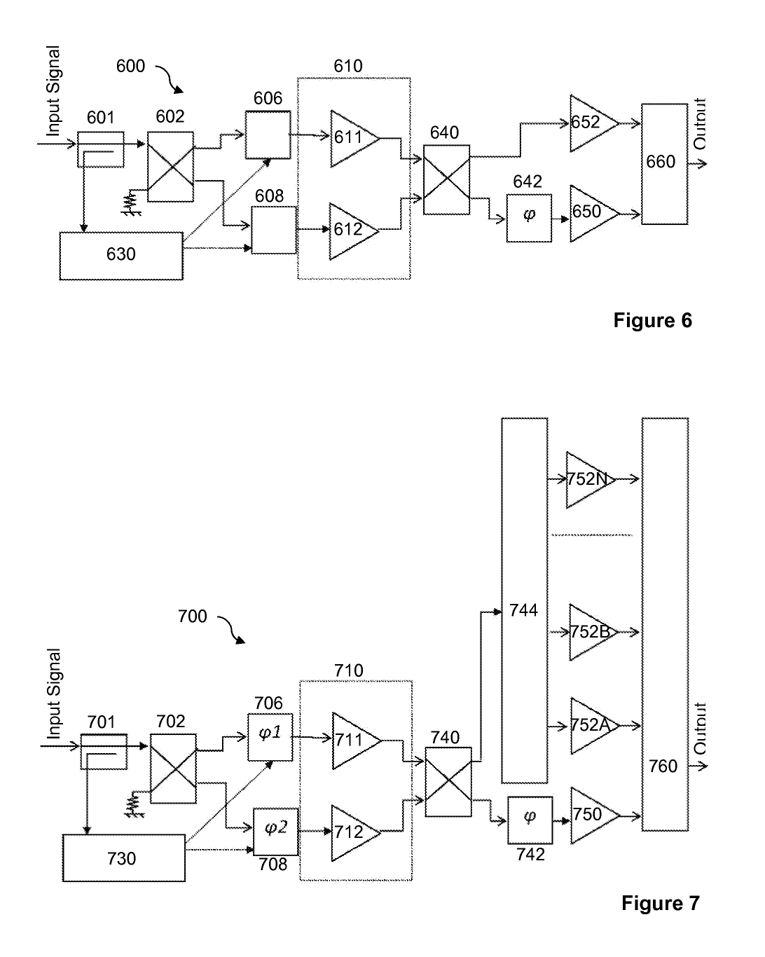

Yet another embodiment of an improved Doherty amplifier 600 is presented in FIG. 6, which includes first and second envelope controlled vector modulators (ECVMs) 606 and 608, rather than the envelope controlled phase shifters of FIG. 2. It is contemplated that the ECVMs 606 and 608 can control the respective phases φ₁ and φ₂ of the first and second input signals using the same relationships as described in the embodiment shown in FIG. 2. In addition, it is contemplated that the ECVMs 606 and 608 may have dynamically controlled attenuation, which could be used to maintain a constant amplifier gain across a dynamic range of the input signal, thus obtaining better amplifier linearity. With respect to the remaining numerals in FIG. 6, the same considerations for like components with like numerals of FIG. 2 apply.

Another embodiment is presented in FIG. 7, which provides for an N-way Doherty amplifier 700. The Doherty amplifier 700 can include an n-way splitter 744 coupled with the outputs from the input hybrid coupler 740, and be configured to provide inputs to the multi-path auxiliary amplifiers 752A-752N. A Doherty combiner 760 can be used to sum the outputs of the main amplifier 750 and the auxiliary amplifiers 752A-752N to produce an amplified signal output. With respect to the remaining numerals in FIG. 7, the same considerations for like components with like numerals of FIG. 2 apply.

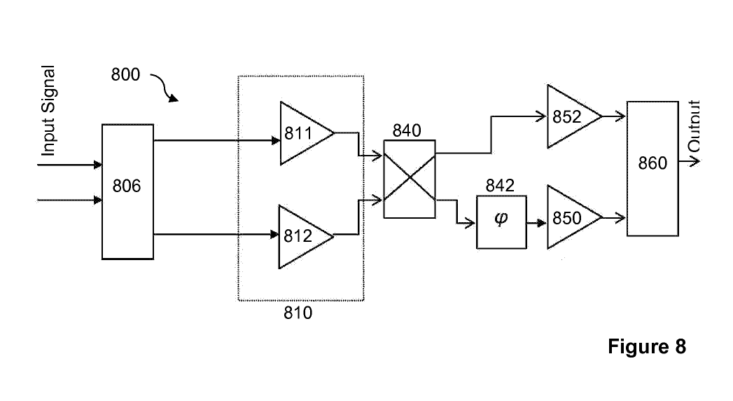

Still another embodiment is shown in FIG. 8, which provides for an IQ input signal based system. The system is based on an input IQ signal that is digitally processed and/or up-converted into RF channels, each feeding an input of an RF driver. Because the envelope is given, it is not necessary to measure the input signal's envelope. The digital signal processor (DSP) 806 maintains the amplitude and phase relations of both drivers input signals, and preferably in an identical relationship as described in the embodiments of FIGS. 2 and 4. Thus, at smaller input signals, the majority of the driver power (approx. 51-100%) goes to the main amplifier 850, while at full power, the driver power is split between the main and auxiliary amplifiers 850 and 852 in 1:1 ratio or any other suitable ratio that is sufficient to obtain specific efficiency levels and linearity of the Doherty amplifier 800 (e.g., 20%-70%, more preferably 40%-60%). With respect to the remaining numerals in FIG. 8, the same considerations for like components with like numerals of FIG. 2 apply.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A Doherty amplifier, comprising:
an input hybrid coupler comprising a first input and a second input; and
a first and second driver that individually drive the first and the second input, respectively.

2. The amplifier of claim 1, wherein the first driver is configured to receive a first input signal having a first input phase and a first input amplitude, and wherein the second driver is configured to receive a second input signal having a second input phase and a second input amplitude.

3. The amplifier of claim 2, wherein the first and second input phases are dynamically adjusted across a dynamic range.

4. The amplifier of claim 3, wherein each of the first input phase, the second input phase, the first input amplitude, and the second input amplitude is dynamically adjusted across the dynamic range.

5. The amplifier of claim 3, wherein the dynamic range is between 5 dB to 15 dB.

6. The amplifier of claim 5, wherein the dynamic range is between 10 dB to 15 dB.

7. The amplifier of claim 3, further comprising an input signal controller configured to dynamically adjust the first and second input phases across the dynamic range as a function of an input signal envelop power.

8. The amplifier of claim 7, further comprising:
a first and a second signal modulator configured to control the first and second input phases, respectively; and
wherein the input signal controller is further configured to communicate with the first and second signal modulators to dynamically adjust the first and second input phases, respectively, across the dynamic range as the function of the input signal envelop power.

9. The system of claim 8, wherein the first signal modulator comprises a phase shifter.

10. The system of claim 8, wherein the first signal modulator comprises a vector modulator.

11. The amplifier of claim 3, further comprising at least one of a hybrid coupler, a directional couple, and a DSP.

12. The amplifier of claim 2, wherein the first and second input phases are dynamically adjusted across a dynamic range to maintain a constant output signal phase across the dynamic range.

13. The amplifier of claim 2, wherein signal amplitudes at the first and second inputs of the first and second drivers, respectively, are not equal.

14. The amplifier of claim 1, wherein input phases of a first and a second input signal of the first and second drivers, respectively, are adjusted as a function of an input signal envelop power.

15. The amplifier of claim 1, further comprising a multi-path auxiliary amplifier coupled with outputs from the input hybrid coupler.

16. The amplifier of claim 15, further comprising an n-way splitter coupled with the outputs from the input hybrid coupler, and that is configured to provide inputs to the multi-path auxiliary amplifier.
